(19) United States
(12) Patent Application Publication
(10) Pub. No.: US 2009/0059682 A1
(43) Pub. Date: Mar. 5, 2009

(54) SEMICONDUCTOR MEMORY DEVICE HAVING ANTIFUSE CIRCUITRY

(76) Inventors: Bok-Gue Park, Hwaseong-si (KR); Sang-Jae Rhee, Seongnam-si (KR); Jae-Youn Youn, Seoul (KR)

Correspondence Address: F. CHAU & ASSOCIATES, LLC, 130 WOODBURY ROAD, WOODBURY, NY, 11797, US

(21) Appl. No.: 12/202,902

(22) Filed: Sep. 2, 2008

(30) Foreign Application Priority Data
Aug. 30, 2007 (KR) 10-2007-0087518

(51) Int. Cl. G11C 7/00; G11C 29/00; G11C 8/00

(52) U.S. Cl. 365/189.07; 365/225.7; 365/230.03; 365/200

(57) ABSTRACT

A semiconductor memory device includes a fuse box including a plurality of address antifuse circuits, each address antifuse circuit outputting an address fuse signal according to a program state of an antifuse included in the corresponding address antifuse circuit, an address comparator including a plurality of address comparison signal generators, each address comparison signal generator combining a first test signal for determining an initial defect of the antifuse and a corresponding bit of an externally applied address signal to generate a test address, and comparing the test address with the address fuse signal to generate an address comparison signal, and a redundant enable signal generator for enabling a redundancy enable signal in response to a plurality of address comparison signals.

### CROSS-REFERENCE TO RELATED APPLICATION

This application is based on and claims the benefit of Korean Patent Application No. 2007-0087518, filed Aug. 30, 2007, the disclosure of which is incorporated by reference herein.

### BACKGROUND OF THE INVENTION

1. Field of the Invention

The present invention relates to a semiconductor memory device and, more particularly, to a semiconductor memory device having an antifuse circuit.

2. Description of the Related Art

During fabrication of a semiconductor memory device, even when only one of a great number of memory cells is defective, the semiconductor memory device is rejected as a failed one. However, discarding the semiconductor memory device as a failed one due to defects in one or more of the memory cells reduces productivity. Conventionally, a defective memory cell has been replaced with a pre-fabricated redundant cell in order to repair the memory device.

During a repair operation using a redundant cell, a redundant row and a redundant column are pre-fabricated for each memory cell array so that a row or column of memory cells including a defective memory cell may be replaced with the redundant row or redundant column. After a wafer is manufactured and a defective memory cell is detected via a test, an internal circuit performs a program operation replacing an address of the defective memory cell with an address of a redundant cell. Thus, when an address signal corresponding to a defective line is addressed, the redundant line is accessed instead of the defective line.

A repair operation may be also performed using a fuse. In this case, a semiconductor memory device is repaired at a wafer level. For this reason, after a package assembly is completed, even when the semiconductor memory device turns out to have a defective memory cell, the repair operation cannot be performed. In order to overcome this drawback, antifuses may be used to repair defects.

An antifuse has electrical characteristics opposite to those of a fuse. Specifically, the antifuse is a resistive fuse that has a high resistance of, for example, 100 MΩ before activation using a program operation and has a low resistance of, for example, 100 KΩ or lower after activation. The antifuse is typically formed of a very thin dielectric material, such as a composite formed by interposing a dielectric material, such as SiO₂, silicon nitride, tantalum oxide, or silicon dioxide-silicon nitride-silicon dioxide (ONO), between two conductive materials. During the program operation of the antifuse, a high voltage of, for example, about 10V, is applied to antifuse terminals for a sufficient time to destroy the dielectric material. Thus, when the antifuse is programmed, an electrical short occurs between the two conductive materials of the antifuse, thereby reducing the resistance of the antifuse. Therefore, the antifuse is electrically open before the program operation and becomes an electrical short after the program operation.

As described above, an antifuse is used to repair a circuit and may be programmed not only at a wafer level but also at a package level. When the antifuse is unprogrammed, the antifuse remains open so as to increase the stability of a semiconductor memory device. However, even when the antifuse is not programmed, the antifuse may be shorted due to fabrication problems, static electricity, or initial defects, such as an abnormal power supply voltage. When a high voltage is applied to the antifuse having the electrical short so as to program the antifuse, an internal circuit of the semiconductor memory device may be damaged. Also, when the antifuse is defective, even when a repair operation is performed, the semiconductor memory device is still rejected as a failed one, thereby reducing productivity. Even when the antifuse does not have an initial defect, it is necessary to determine the state of the antifuse in order to see whether a repair operation can be normally performed.

### SUMMARY OF THE INVENTION

Exemplary embodiments of the invention provide a semiconductor memory device including antifuses, which can easily determine whether the antifuses have initial defects and whether a repair operation is normally performed.

An exemplary embodiment of, the present invention is directed to a semiconductor memory device including a fuse box including a plurality of address antifuse circuits, each address antifuse circuit outputting a corresponding address fuse signal corresponding to a program state of a corresponding antifuse included in the corresponding address antifuse circuit; an address comparator including a plurality of address comparison signal generators, each address comparison signal generator comparing a first test signal for determining an initial defect of the corresponding antifuse and a corresponding bit of an externally applied address signal to generate a corresponding test address, and comparing the corresponding test address with the corresponding address fuse signal to generate a corresponding address comparison signal; and a redundant enable signal generator for producing a redundant enable signal in response to a plurality of address comparison signals generated by the plurality of addresses comparison signal generators.

The fuse box may further include a master antifuse circuit, which outputs a master fuse signal for designating whether to use the fuse box according to a program state of an antifuse included in the master antifuse circuit.

The address comparator may further include a block address comparison signal generator, which compares a second test signal for determining whether the plurality of address antifuse circuits are normally programmed, and a block address corresponding to the fuse box to generate a test block address, and compare the test block address with the master fuse signal to generate a block address comparison signal.

The redundant enable signal generator may produce the redundant enable signal in response to the plurality of address comparison signals and the block address comparison signal.

The address comparison signal generator may include a first inverter for inverting the first test signal; a first AND gate for performing a logic AND on an output signal of the first inverter and the corresponding bit of the address signal to output a corresponding test address; and a first XNOR gate for performing a logic exclusive NOR (XNOR) on the corresponding test address and the corresponding address fuse signal to output the corresponding address comparison signal.

The block address comparison signal generator may include a second inverter for inverting the second test signal; a second AND gate for performing a logic AND on an output signal of the second inverter and the block address to output the test block address; and a second XNOR gate for performing a logic XNOR on the test block address and the master fuse signal to output the block address comparison signal.

Each of the first and second test signals may be enabled in response to a mode register set (MRS) signal.

The semiconductor memory device may externally output the redundant enable signal through a data pin or an additional test pin.

The semiconductor memory device may further include a normal address disable signal generation circuit, which generates a normal address disable signal when at least one of the redundant enable signals is enabled.

The normal address disable signal generation circuit may include a PMOS transistor connected between a first power supply voltage and a first node and having a gate to which an active command is applied; a plurality of NMOS transistors connected in parallel between a second power supply voltage and the first node and having gates to which the corresponding ones of the redundant enable signals are respectively applied; and a latch unit for inverting a signal of the first node and latching the signal of the first node to output the normal address disable signal.

The semiconductor memory device may further include a memory cell array comprising a normal cell array including a plurality of memory blocks each having a plurality of normal memory cells connected between a plurality of word lines and a bit lines and, a redundant cell array including a plurality of redundant memory cells connected between a plurality of redundant word lines and bit lines; a decoder unit for selecting the normal cell array or the redundant cell array in response to the normal address disable signal, and selecting the normal memory cell in response to the externally applied address signal and the block address or selecting the redundant memory cell in response to the redundant enable signal; an input/output sense amplifier for sensing and amplifying a data signal of the normal memory cell or redundant memory cell selected by the decoder unit to output an amplified signal; a multiplexer for selecting the normal address disable signal or the data signal in response to the second test signal to output a selected signal; and a data input/output unit for externally outputting the normal address disable signal or the data signal output by the multiplexer through a data pin or a test pin.

The decoder unit may select the redundant word line in response to the redundant enable signal, and select the redundant bit line in response to the redundant enable signal.

### BRIEF DESCRIPTION OF THE DRAWINGS

Exemplary embodiments of the present invention will become apparent by reference to the following detailed description taken in conjunction with the accompanying drawings, wherein:

FIG. 1 is a block diagram of a repair circuit according to an exemplary embodiment of the present invention; and

FIG. 2 is a circuit diagram of a normal address disable signal generation circuit according to an exemplary embodiment of the present invention.

### DETAILED DESCRPTION OF THE INVENTION

Hereinafter, exemplary embodiment of the present invention will be described in detail with reference to the accompanying drawings.

In a semiconductor memory device, in order to determine whether an antifuse has an initial defect or a repair operation was normally performed, it is necessary to examine whether the antifuse has a defect before the antifuse is programmed. When it is determined that the antifuse has no initial defect, an address antifuse circuit is programmed and then it is determined whether the address antifuse circuit is normally programmed. When it is determined that the address antifuse circuit is normally programmed, a master antifuse circuit is programmed and then it is finally determined whether the repair operation was normally completed. In order to increase a yield of the semiconductor memory devices and reduce unnecessary work, when the address antifuse circuit is not properly programmed, the master antifuse circuit is not programmed. In contrast, after it is determined that the address antifuse circuit is normally programmed, the master antifuse circuit is programmed.

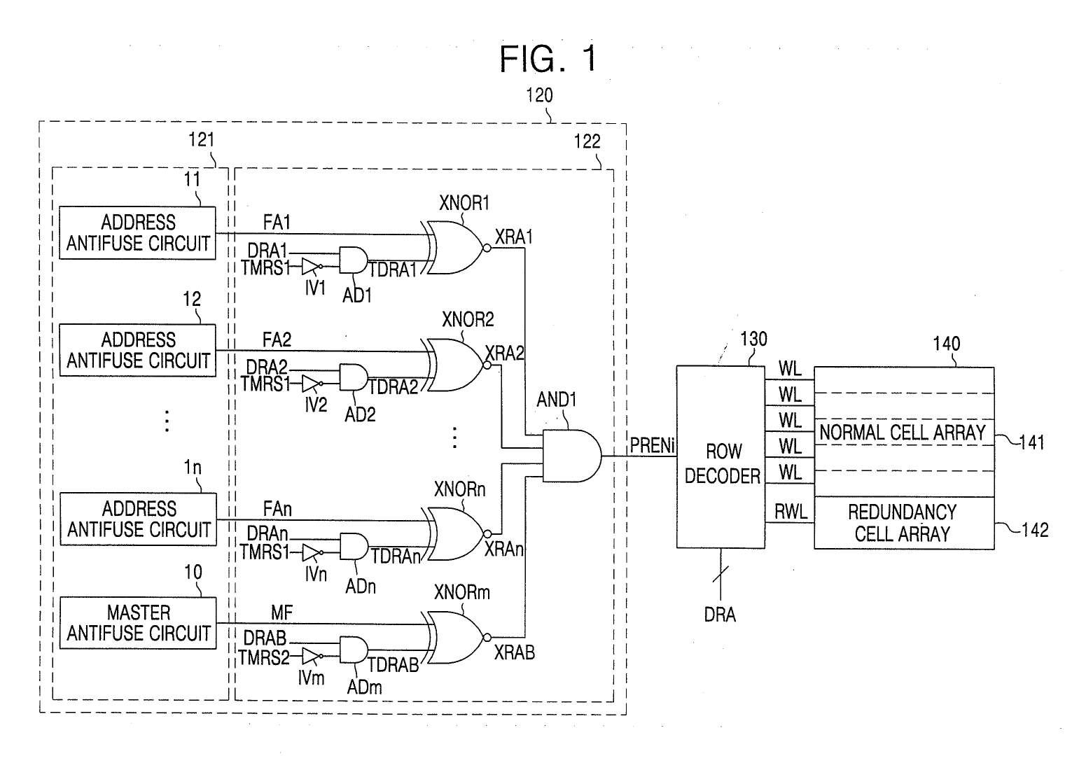

FIG. 1 is a block diagram of a repair circuit according to an exemplary embodiment of the present invention.

Referring to FIG. 1, the repair circuit 120 includes a plurality of fuse boxes 121 and a plurality of redundant enable units 122 corresponding respectively to redundant rows included in a redundant cell array 142. However, for simplicity, FIG. 1 illustrates one fuse box 121 and one redundant enable unit 122.

Each of the fuse boxes 121 includes a master antifuse circuit 10 and a plurality of address antifuse circuits 11 to 1n. The master antifuse circuit 10 determines whether the fuse box 121 is used. Also, one of the address antifuse circuits 11 to 1n corresponding to an address of a defective memory cell is programmed so as to designate the address of the defective memory cell.

The master antifuse circuit 10 receives a decoded row block address DRAB, and each of the address antifuse circuits 11 to 1n receives 1 bit of the decoded row addresses DRA1 to DRAn corresponding to a defective memory cell. When a defective memory cell included in the memory block of the normal cell array 141 is to be replaced with a redundant memory cell, the master antifuse circuit 10 programs an antifuse and outputs a master fuse signal MF to indicate whether to use the fuse box 121. Also, the address antifuse circuits 11 to 1n output address fuse signals FA1 to FAn to designate corresponding bits of the decoded row addresses DRA1 to DRAn of the defective memory cell.

The redundancy enable unit 122 does not directly compare the address fuse signals FA1 to FAn with the respective bits of the decoded row addresses DRA1 to DRAn.

A plurality of inverters IV1 to IVn receive a first test signal TMRS1, invert the first test signal TMRS1, and output the inverted signal. The first test signal TMRS1 is enabled in response to a mode register set (MRS) signal, such as a program mode selection signal SEL. In an exemplary embodiment, the first test signal TMRS1 is a test signal used for determining whether the antifuse included in the master antifuse circuit 10 or in the address antifuse circuits 11 to 1n is defective. A plurality of AND gates AD1 to ADn perform a logic AND on the respective bits of the decoded row addresses DRA1 to DRAn and output signals of the inverters IV1 to IVn, respectively, to output a plurality of test addresses TDRA1 to TDRAn, respectively. Also, a plurality of XNOR gates XNOR1 to XNORn compare the address fuse signals FA1 to FAn with the test addresses TDRA1 to TDRAn, respectively, and determine whether the address fuse signals FA1 to FAn are equal to the test addresses TDRA1 to TDRAn, respectively. When the address fuse signals FA1 to FAn are equal to the test addresses TDRA1 to TDRAn, respectively, the XNOR gates XNOR1 to XNORn output high-level address comparison signals XRA1 to XRAn, respectively. However, when the address fuse signals FA1 to FAn are not equal to the test addresses TDRA1 to TDRAn, respectively, the XNOR gates XNOR1 to XNORn output low-level address comparison signals XRA1 to XRAn, respectively.

An inverter IVm receives a second test signal TMRS2, inverts the second test signal TMRS2, and outputs the inverted signal. The second test signal TMRS2 is also enabled in response to an MRS signal. However, unlike the first test signal TMRS1, the second test signal TMRS2 is required to determine whether the address antifuse circuits 11 to 1n are normally programmed. An AND gate ADm performs a logic AND on a decoded row block address DRAB and an output signal of the inverter IVm and outputs a test block address TDRAB. An XNOR gate XNORm compares the master fuse signal MF with the test block address TDRAB and determines whether the master fuse signal MF is equal to the test block address TDRAB. When the master fuse signal MF is equal to the test block address TDRAB, the XNOR gate XNORm outputs a high-level block address comparison signal XRAB. When the master fuse signal MF is not equal to the test block address TDRAB, the XNOR gate XNORm outputs a low-level block address comparison signal XRAB. An AND gate AND1 performs a logic AND on a plurality of address comparison signals XRA1 to XRAn and the block address comparison signal XRAB and outputs a redundant enable signal PRENi.

To determine whether the antifuse included in the master antifuse circuit 10 and the address antifuse circuits 11 to 1n has an initial defect, the first test signal TMRS1 and the second test signal TMRS2 are enabled to a high level. Since all the antifuses are unprogrammed, to determine whether the antifuses have initial defects via a test, the master fuse signal MF and the address fuse signals FA1 to FAn are output at a low level. Since the first test signal TMRS1 is at a high level, and the plurality of inverters IV1 to IVn output low-level signals, the plurality of AND gates AD1 to ADn output low-level test addresses TDRA1 to TDRAn. Also, the AND gate ADm receives a low-level signal, which is obtained by inverting the high-level second test signal TMRS2 via the inverter IVm, and outputs a low-level test block address TDRAB. That is, all the AND gates AD1 to ADn and ADm output low-level signals. As described above, the master fuse signal MF and the address fuse signals FA1 to FAn are output at a low level, and the AND gates AD1 to ADn and ADm are also output at a low-level. Therefore, when the antifuses have no initial defect, a plurality of XNOR gates XNOR1 to XNORn and XNORm output high-level address comparison signals XRA1 to XRAn and a high-level block address comparison signal XRAB, respectively. The AND gate AND1 outputs a high-level redundant enable signal PRENi in response to the high-level address comparison signals XRA1 to XRAn and the high-level block address comparison signal XRAB.

However, when an antifuse of at least one of the master antifuse circuit 10 or the address antifuse circuits 11 to 1n has an initial defect, the antifuse circuit which includes the antifuse with the initial defect, outputs a high-level signal. Thus, the corresponding XNOR gates XNOR1 to XNORn or XNORm receives the high-level signal and outputs a low-level address comparison signal. As a result, the AND gate AND1 outputs a low-level redundant enable signal PRENi in response to the low-level address comparison signal.

In other words, when a plurality of antifuses included in the fuse box 121 have no defect, the redundant enable signal PRENi is enabled to a high level so that the row decoder 130 enables a redundant word line (RWL) for selecting the corresponding redundant row of the redundant cell array 142. However, when the antifuses included in the fuse box 121 have at least one defect, the redundant enable signal PRENi is disabled to a low level so that the row decoder 130 enables a word line (WL) for selecting the corresponding row of the normal cell array 141 in response to a decoded row address DRA.

In order to enable a test operation, data “1” or data “0” is stored in all the memory cells of the normal cell array and in all the memory cells of the redundant cell array 142. Specifically, when data “1” is stored in all the memory cells of the normal cell array 141, data “0” is stored in all the memory cells of the redundant cell array 142, and when data “0” is stored in all the memory cells of the normal cell array 141, data “1” is stored in all the memory cells of the redundant cell array 142. Thus, by examining the stored data, it can be determined whether the current data that is externally output from the semiconductor memory device is data stored in the memory cell of the normal cell array 141 or data stored in the memory cell of the redundant cell array 142. Accordingly, supposing data “1” is stored in the memory cell of the normal cell array 141 and data “0” is stored in the memory cell of the redundant cell array 142, when the semiconductor memory device outputs data “0”, it is determined that the antifuses included in the fuse box 121 have no defect, however, when the semiconductor memory device outputs data “1”, it is determined that at least one of the antifuses included in the fuse box 121 has a defect.

When the antifuses of the fuse box 121 have no initial defect, an address of a defective memory cell of the semiconductor memory device is determined via a variety of tests. Thereafter, an address antifuse circuit of the fuse box 121 corresponding to a memory block including the determined defective memory cell is programmed, and then it is necessary to determine whether the corresponding address antifuse circuit is normally programmed. In order to perform the determination operation, the first test signal TMRS1 is disabled to a low level and the second test signal TMRS2 is enabled to a high level.

Since the first test signal TMRS1 is disabled to a low level, a plurality of inverters IV1 to IVn output high-level signals, and a plurality of AND gates AD1 to ADn output test addresses TDRA1 to TDRAn at the same level as decoded row addresses DRA1 to DRAn, respectively. Here, the decoded row addresses DRA1 to DRAn are decoded addresses of defective addresses, which are determined via a test, and programmed in a plurality of address antifuse circuits 11 to 1n of the fuse box 121. Thus, when the address fuse signals FA1 to FAn are equal to the decoded row addresses DRA1 to DRAn, it is determined that the address antifuse circuits 11 to 1n are normally programmed.

A plurality of XNOR gates XNOR1 to XNORn compare the address fuse signals FA1 to FAn with the test addresses TDRA1 to TDRAn, respectively, and output high-level signals when all the address fuse signals FA1 to FAn are equal to the test addresses TDRA1 to TDRAn, respectively. That is, when the address antifuse circuits 11 to 1n are normally programmed, all the XNOR gates XNOR1 to XNORn output high-level address comparison signals XRA1 to XRAn, respectively.

Since the second test signal TMRS2 is enabled to a high level, the inverter IVm outputs a low-level signal, and the AND gate ANDm outputs a low-level test block address TDRAB. Since the master antifuse circuit 10 is still not programmed during the test operation of determining whether the address antifuse circuits 11 to 1n are normally programmed, the master fuse signal MF is at a low level. Thus, the XNOR gate XNORm outputs a high-level block address comparison signal XRAB in response to the low-level master fuse signal MF and the low-level test block address TDRAB. The AND gate AND1 outputs a high-level redundant enable signal PRENi in response to the address comparison signals XRA1 to XRAn and the block address comparison signal XRAB.

As in the test operation of determining whether antifuses have initial defects, when the address antifuse circuits 11 to 1n are normally programmed, the repair circuit 120 outputs a high-level redundant enable signal PRENi, and when the address antifuse circuits 11 to 1n are not properly programmed, the repair circuit 120 outputs a low-level redundant enable signal PRENi.

When the address antifuse circuits 11 to 1n are normally programmed, the master antifuse circuit 10 is programmed. In order to determine whether all the antifuses included in the fuse box 121 including the antifuse of the master antifuse circuit 10 are programmed normally, the first test signal TMRS1 and the second test signal TMRS2 are disabled to a low level.

The inverters IV1 to IVn and IVm invert the low-level first test signal TMRS1 and the low-level second test signal TMRS2 and output high-level signals, respectively. The AND gates AD1 to ADn output test addresses TDRA1 to TDRAn at the same level as decoded row addresses DRA1 to DRAn in response to output signals of the inverters IV1 to IVn and the decoded row addresses DRA1 to DRAn, respectively. Also, the AND gate ADm outputs a test block address TDRAB at the same level as a decoded row block address DRAB in response to an output signal of the inverter IVm and the decoded row block address DRAB. Since the test for determining whether the address antifuse circuits 11 to 1n are normally programmed is already performed, all the XNOR gates XNOR1 to XNORn output high-level address comparison signals XRA1 to XRAn. When the master antifuse circuit 10 is normally programmed, the master fuse signal MF is at a high level. Also, when the corresponding block is selected, since the decoded row block address DRAB is also at a high level, the XNOR gate XNORm outputs a high-level block address comparison signal XRAB.

Accordingly, the repair circuit 120 outputs a high-level redundant enable signal PRENi when the master antifuse circuit 10 is normally programmed, and outputs a low-level redundant enable signal PRENi when the master antifuse circuit 10 is not properly programmed.

As a result, the repair circuit 120 according to the present invention can test whether the antifuses have initial defects, whether the address antifuse circuits 11 to 1n are normally programmed, and whether the master antifuse circuit 10 is normally programmed, according to levels of the first and second test signals TMRS1 and TMRS2, and output test results. Therefore, the test results can be easily determined, and a test time can be shortened. Also, since the test results are output in response to an address that is applied during a test operation, it is easy to detect the defective fuse box 121.

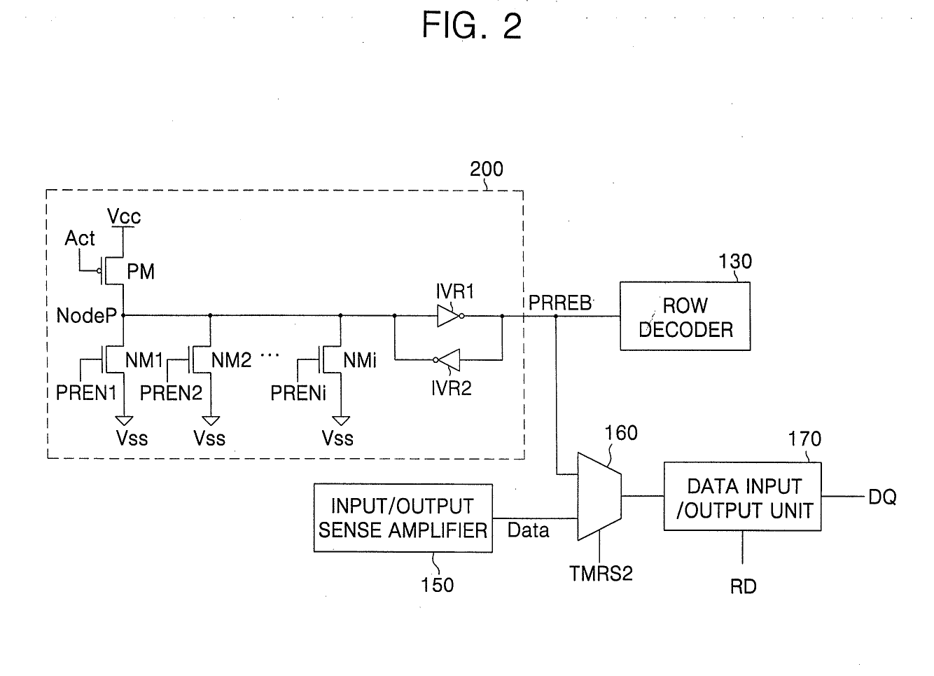

FIG. 2 is a circuit diagram of a normal address disable signal generation circuit according to an exemplary embodiment of the present invention.

The repair circuit 120 shown in FIG. 1 further includes a normal address disable signal generation circuit 200. When an externally applied address is an address of a defective memory cell, the normal address disable signal generation circuit 200 applies a normal address disable signal PRREB to the row decoder 130 so that the row decoder 130 selects a memory cell of the redundant cell array 142 instead of a memory cell of the normal cell array 141.

In the above-described test operation, the memory cells of the normal cell array 141 store different data than the memory cells of the redundant memory cell 142, and a test result is determined based on output data. However, in the current test operation, no data is stored in the memory cells of the memory cell array 140, and a result of a test performed on an antifuse circuit is determined using the normal address disable signal generation circuit 200.

A PMOS transistor PM is connected between a power supply voltage Vcc and a P node NodeP and has a gate to which an active signal Act is applied. The active signal Act is transmitted from a command decoder (not shown) of the semiconductor memory device. The active signal Act is enabled during a read or write operation of the semiconductor memory device and disabled during a precharge operation. Also, a plurality of NMOS transistors NM1 to NMi are connected in parallel between the P node NodeP and a ground voltage Vss and have gates to which redundant enable signals PERN1 to PERNi are applied. A latch comprised of two inverters IVR1 and IVR2 inverts a signal of the P node NodeP, latches the signal of the P node NodeP, and outputs a normal address disable signal PRREB.

The row decoder 130 enables a redundant row of the redundant cell array 142 in response to the normal address disable signal PRREB. An input/output sense amplifier 150 senses a data signal Data of a memory cell of the memory cell array 140, which is selected by the row decoder 130 and a column decoder (not shown), amplifies the data signal Data, and outputs the amplified data signal. A multiplexer 160 selects the normal address disable signal PRREB or the data signal Data in response to the second test signal TMRS2 and outputs the selected signal to a data input/output unit 170. The data input/output unit 170 externally outputs the received normal address disable signal PRREB or data signal Data in response to a read command RD.

During precharge operation, since the active signal Act is at a low level, a PMOS transistor PM is turned on, and the P node NodeP is precharged to a power supply voltage (Vcc) level. The inverter IVR1 inverts the signal of the P node NodeP and outputs a low-level normal address disable signal PRREB. Although the row decoder 130 and the multiplexer 160 receive the low-level normal address disable signal PRREB, since the semiconductor memory device performs the precharge operation, the row decoder 130 does not perform the corresponding operation. Also, the multiplexer 160 selects the data signal Data in response to the second test signal 160.

When the semiconductor memory device performs an active operation and the second test signal TMRS2 is enabled, the PMOS transistor PM is turned off, and the P node NodeP is floated. Also, a plurality of NMOS transistors NM1 to NMi receive a plurality of redundant enable signals PREN1 to PRENi, respectively, from the repair circuit 120 shown in FIG. 1. When all the redundant enable signals PREN1 to PRENi are at a low level, the inverter IVR1 inverts the signal of the P node NodeP and outputs a low-level normal address disable signal PRREB. However, when at least one of the redundant enable signals PREN1 to PRENi is enabled to a high level, the signal of the P node NodeP is sent to a ground voltage (Vss) level. The inverter IVR1 inverts the signal of the P node NodeP and outputs a high-level normal address disable signal PRREB. Also, the multiplexer 160 selects the normal address disable signal PRREB in response to the second test signal TMRS2, and the data input/output unit 170 externally outputs the normal address disable signal PRREB in response to the read command RD.

Therefore, the semiconductor memory device including the repair circuit 120 of FIG. 1 and the normal address disable signal generation circuit 200 of FIG. 2 can determine whether the antifuse circuits of the repair circuit 120 have initial defects and whether the antifuse circuits are normally programmed based on output data DQ that is output via a data pin. Since the output data DQ is output as a digital value at a high level or a low level, it is possible to determine whether the antifuse circuits are normally programmed testing in a short time. Also, since the output data DQ is output to correspond to an address applied to the semiconductor memory device, a defective antifuse circuit can be easily isolated from a plurality of antifuse circuits.

Although in the exemplary embodiments described above, a row of the normal cell array 141 is replaced with a redundant row of the redundant cell array 142, it is also possible that a column of the normal cell array 141 may be replaced with a redundant column of the redundant cell array 142. Furthermore, although it is described with reference to FIG. 2 that a test result of the repair circuit 120 is the output data DQ output via a data pin, the semiconductor memory device may further include an additional test pin to output the test result.

As described above, a semiconductor memory device according to exemplary embodiments of the present invention can not only determine whether antifuses have initial defects but also whether the antifuses are normally programmed. Therefore, defective antifuses can be easily found in a short time period.

Although exemplary embodiments of the present invention have been described for illustrative purposes, those skilled in the art will appreciate that various modifications, additions and substitutions are possible, without departing from the scope and spirit of the disclosure.

What is claimed is:

1. A semiconductor memory device, comprising:
a fuse box including a plurality of address antifuse circuits, each address antifuse circuit outputting a corresponding address fuse signal corresponding to a program state of a corresponding antifuse included in the corresponding address antifuse circuit;
an address comparator including a plurality of address comparison signal generators, each address comparison signal generator comparing a first test signal for determining an initial defect of the corresponding antifuse and a corresponding bit of an externally applied address signal to generate a corresponding test address, and comparing the corresponding test address with the corresponding address fuse signal to generate a corresponding address comparison signal; and
a redundant enable signal generator for producing a redundant enable signal in response to a plurality of address comparison signals generated by the plurality of address comparison signal generators.

2. The device according to claim 1, wherein the fuse box further comprises a master antifuse circuit for outputting a master fuse signal for designating whether to use the fuse box according to a program state of an antifuse included in the master antifuse circuit.

3. The device according to claim 2, wherein the address comparator further comprises a block address comparison signal generator for comparing a second test signal, for determining whether the plurality of address antifuse circuits are normally programmed, and a block address corresponding to the fuse box to generate a test block address, and comparing the test block address with the master fuse signal to generate a block address comparison signal.

4. The device according to claim 3, wherein the redundant enable signal generator produces the redundant enable signal in response to the plurality of address comparison signals and the block address comparison signal.

5. The device according to claim 4, wherein the address comparison signal generator comprises:
a first inverter for inverting the first test signal;
a first AND gate for performing a logic AND on an output signal of the first inverter and the corresponding bit of the address signal to output a corresponding test address; and
a first XNOR gate for performing a logic exclusive NOR (XNOR) on the corresponding test address and the corresponding address fuse signal to output the corresponding address comparison signal.

6. The device according to claim 5, wherein the block address comparison signal generator comprises:
a second inverter for inverting the second test signal;
a second AND gate for performing a logic AND on an output signal of the second inverter and the block address to output the test block address; and
a second XNOR gate for performing a logic XNOR on the test block address and the master fuse signal to output the block address comparison signal.

7. The device according to claim 4, wherein each of the first and second test signals is enabled in response to a mode register set (MRS) signal.

8. The device according to claim 4, wherein the redundant enable signal is externally output through one of a data pin or an additional test pin.

9. The device according to claim 4, further comprising a normal address disable signal generation circuit for generating a normal address disable signal when at least one of the redundant enable signals is enabled.

10. The device according to claim 9, wherein the normal address disable signal generation circuit comprises:
a PMOS transistor connected between a first power supply voltage and a first node and having a gate to which an active command is applied;
a plurality of NMOS transistors connected in parallel between a second power supply voltage and the first node and having gates to which the corresponding ones of the redundant enable signals are respectively applied; and
a latch unit for inverting a signal of the first node and latching the signal of the first node to output the normal address disable signal.

11. The device according to claim 9, further comprising:
a memory cell array comprising a normal cell array including a plurality of memory blocks each having a plurality of normal memory cells connected between a plurality of word lines and bit lines, and a redundant cell array including a plurality of redundant memory cells connected between a plurality of redundant word lines and bit lines;
a decoder unit for selecting one of the normal cell array or the redundant cell array in response to the normal address disable signal, and selecting the normal memory cell in response to the externally applied address signal and the block address or selecting the redundant memory cell in response to the redundant enable signal;
an input/output sense amplifier for sensing and amplifying a data signal of one of the normal memory cell or the redundant memory cell selected by the decoder unit to output an amplified signal;
a multiplexer for selecting one of the normal address disable signal or the amplified signal in response to the second test signal to output a selected signal; and
a data input/output unit for externally outputting the selected signal output by the multiplexer through one of a data pin or a test pin.

12. The device according to claim 11, wherein the decoder unit selects the redundant word line in response to the redundant enable signal.

13. The device according to claim 11, wherein the decoder unit selects the redundant bit line in response to the redundant enable signal.

14. A semiconductor memory device, comprising:
a fuse box including a plurality of address antifuse circuits, each outputting a corresponding fuse signal; and
a redundant enable unit for producing a redundant enable signal in response to a plurality of address comparison signals, wherein each of the plurality of address comparison signals is generated by comparing a first test signal and an externally applied address signal to produce a test address, and by comparing the test address to the corresponding fuse signal.

15. The device according to claim 14, wherein the fuse box further comprises a master anitfuse circuit for outputting a master fuse signal for controlling whether to use the fuse box.

16. The device according to claim 15, wherein the redundant enable unit includes an address comparator including a plurality of address comparison signal generators.

17. The device according to claim 16, wherein the address comparator compares a second test signal and an address block signal to generate a test block address, and compares the test block address to the master fuse signal to generate a block address comparison signal.

18. The device according to claim 17, wherein the redundant enable unit outputs a redundant enable signal by comparing the block address comparison signal to the plurality of address comparison signals.

19. The device according to claim 18, further comprising a memory cell array including a plurality of a normal cell arrays having a plurality of normal memory cells, and a redundant cell array including a plurality of redundant memory cells.

20. The device of claim 19, further comprising a decoder for selecting one of the memory cells in response to the redundant enable signal.
